(19) United States
(12) Patent Application Publication
(10) Pub. No.: US 2015/0363714 A1
(43) Pub. Date: Dec. 17, 2015

(54) BUSINESS INTELLIGENCE AND ANALYTICS OF ENERGY CONSUMING SYSTEMS

(71) Applicant: ENTIC, LLC, Pembroke Pines, FL (US)

(72) Inventors: Manuel Rosendo, Pembroke Pines, FL (US); Bin Zheng, Palmetto Bay, FL (US)

(21) Appl. No.: 14/307,480

(22) Filed: Jun. 17, 2014

(51) Int. Cl. G06Q 10/06; G06Q 50/06; G05F 1/66; G01R 21/133

(52) U.S. Cl. CPC G06Q 10/0631; G01R 21/133; G06Q 50/06; G05F 1/66

(57) ABSTRACT

A method, system and computer program product for transforming real-time data of an energy consuming system into meaningful and useful data for optimizing Bus Intelligence and Analytics decisions of the energy consuming system, the method including collecting parameter point data from a primary sensor, collecting parameter point data from a second sensor, collecting parameter point data from a third sensor, processing the collected parameter point data from the primary sensor, the second sensor and the third sensor using a triangulation algorithm determining whether the sensor data triangulated, selecting the parameter point data from the primary sensor when the sensor data triangulates, selecting the parameter point data from the processed collected parameter point data from the primary sensor, the second sensor and the third sensor when the sensor data does not triangulate.

### BACKGROUND OF THE INVENTION

1. Field of the Invention

The present invention relates to energy consuming systems and more particularly to converting real-time data into meaningful and useful data of energy consuming systems for optimizing energy efficiency of the energy consuming systems.

2. Description of the Related Art

Business Intelligence is a set of methodologies, processes, architectures, and technologies that transform raw data into meaningful and useful information used to enable more effective strategic, tactical, and operational insights and decision-making Business Intelligence, in simple words, makes interpreting voluminous data friendly. Making use of new opportunities and implementing an effective strategy can provide a competitive market advantage and long-term stability. Business Intelligence can be developed for numerous energy consuming systems, such as chiller plants, air handling systems, lighting systems, elevator systems, water pump stations, oil pump stations, lift stations, solar cell farms, and the like.

To evaluate, operate, and optimize these energy consuming systems, sensors to measure different power and environmental parameters such as temperature, humidity, pressure, water flow, oil viscosity, lighting, sound, thermal signatures, and motor power are needed. Making accurate Business Intelligence and Analytics decisions highly relies on the sensor accuracy, since without sensor accuracy the results of the Business Intelligence and Analytics engine 104 is questionable.

Traditional methods depend on the readings from a single sensor of specific data (e.g., only one sensor is used to read outdoor air temperature or to read outdoor air humidity) and the data from this sensor is used for the control decision. It is very common for these sensors to malfunction and become inaccurate. The inaccurate reading from a single sensor leads to incorrect control decisions, inaccurate control decisions and ultimately inaccurate Business Intelligence and Analytics decisions.

When single point readings from inaccurate sensors are used in Business Intelligence and Analytics systems to evaluate the system performance and develop optimization strategies and control algorithms, the desired optimization results are less often achieved.

Sensor accuracy is critical in making control decisions, evaluating plant performance, and developing and implementing plant energy optimization strategies, all of this done by the Business Intelligence and Analytics algorithms. When and if an inaccurate sensor is detected, to calibrate, to repair and to correct the sensor involves the efforts of multiple parties and the consumption of time. The energy analytics are slowed down and implementations of energy saving measures are delayed. In the meantime, the energy consuming systems are inefficient and, therefore, consume more energy.

### BRIEF SUMMARY OF THE INVENTION

Embodiments of the present invention address deficiencies of the art in respect to Business Intelligence and Analytics of energy consuming systems and provide a novel and non-obvious method, system and computer program product for transforming real-time data of an energy consuming system into meaningful and useful data for optimizing Bus Intelligence and Analytics decisions of an energy consuming system. In an embodiment of the invention, a method for transforming real-time data of an energy consuming system into meaningful and useful data for optimizing Bus Intelligence and Analytics decisions of an energy consuming system can be provided. The method can include collecting parameter point data from a primary sensor, collecting parameter point data from a second sensor, collecting parameter point data from a third sensor, processing the collected parameter point data from the primary sensor, the second sensor and the third sensor using a triangulation algorithm, determining whether the sensor data triangulated, selecting the parameter point data from the primary sensor when the sensor data triangulates and selecting the parameter point data from the processed collected parameter point data from the primary sensor, the second sensor and the third sensor when the sensor data does not triangulate.

In an aspect of this embodiment, the method further can include applying control logic to the parameter point data from the primary sensor when the sensor data triangulates and displaying an analysis of the parameter point data from the primary sensor.

In another embodiment, a computer program product for transforming real-time data of an energy consuming system into meaningful and useful data for optimizing the energy efficiency of the energy consuming system, the computer program product including a computer readable storage medium having computer readable program code embodied therewith, the computer readable program code including computer readable program code for collecting parameter point data from a primary sensor, computer readable program code for collecting parameter point data from a second sensor, computer readable program code for collecting parameter point data from a third sensor, computer readable program code for processing the collected parameter point data from the primary sensor, the second sensor and the third sensor using a triangulation algorithm, computer readable program code for determining whether the sensor data triangulated, computer readable program code for selecting the parameter point data from the primary sensor when the sensor data triangulates computer readable program code for selecting the parameter point data from the processed collected parameter point data from the primary sensor, the second sensor and the third sensor when the sensor data does not triangulate

Additional aspects of the invention will be set forth in part in the description which follows, and in part will be obvious from the description, or may be learned by practice of the invention. The aspects of the invention will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF THE SEVERAL VIEWS OF THE DRAWINGS

The accompanying drawings, which are incorporated in and constitute part of this specification, illustrate embodiments of the invention and together with the description, serve to explain the principles of the invention. The embodiments illustrated herein are presently preferred, it being understood, however, that the invention is not limited to the precise arrangements and instrumentalities shown, wherein:

FIG. 1 is a schematic illustration of a triangulation sensing and analytic system for processing data from an energy consuming system in accordance with one embodiment of the present invention; and,

FIG. 2 is a flow chart illustrating a process for transforming real-time data of an energy consuming system into meaningful and useful data for optimizing Bus Intelligence and Analytics decisions of the energy consuming system.

### DETAILED DESCRIPTION OF THE INVENTION

“Business Intelligence” as used herein is defined as a set of methodologies, processes, architectures, and technologies that transform raw data into meaningful and useful information that is used to enable more effective strategic, tactical, and operational insights and decision-making. Embodiments of the invention provide for a method and process to transform real-time data of an energy consuming system into meaningful and useful data for optimizing Bus Intelligence and Analytics decisions of the energy consuming system, such as chiller plants, air handling systems, lighting systems, elevator systems, water pump stations, oil pump stations, lift stations, solar cell farms, and the like. In one embodiment of the invention, a computer-implemented method for transforming real-time data of energy consuming systems into meaningful and useful data for optimizing the energy efficiency of energy consuming systems includes collecting parameter point data from a primary sensor, collecting parameter point data from a second sensor, collecting parameter point data from a third sensor, processing the collected parameter point data from the primary sensor, the second sensor and the third sensor using a triangulation algorithm determining whether the sensor data triangulated, selecting the parameter point data from the primary sensor when the sensor data triangulates, selecting the parameter point data from the processed collected parameter point data from the primary sensor, the second sensor and the third sensor when the sensor data does not triangulate.

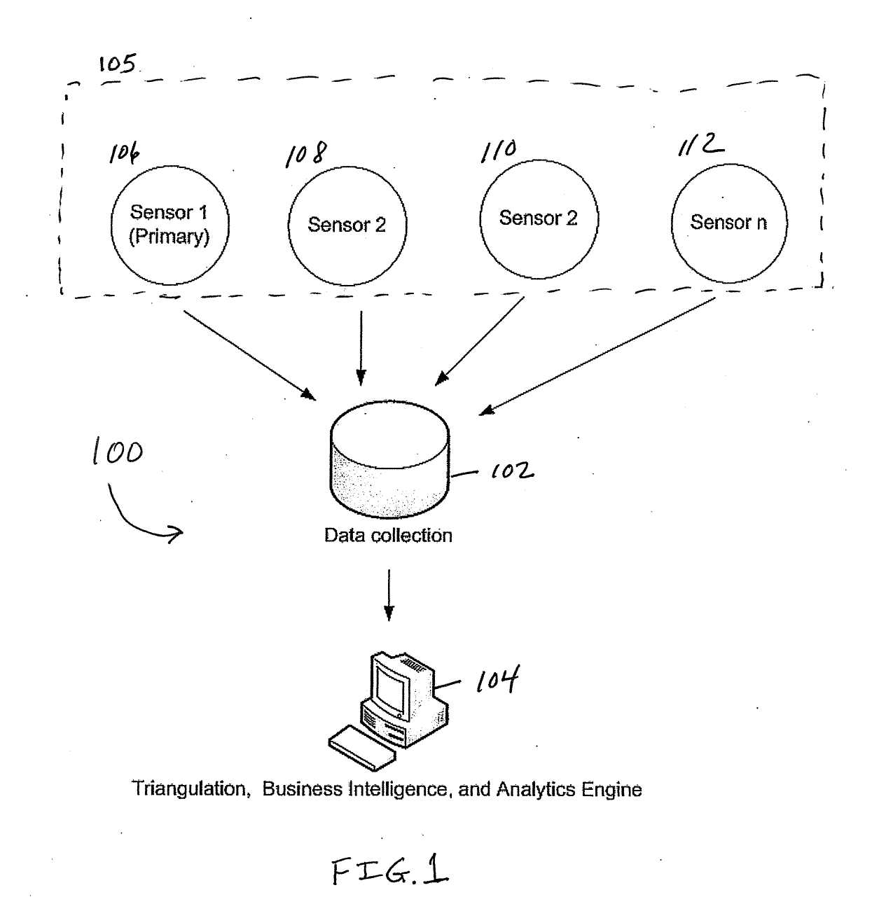

In further illustration, FIG. 1 is a schematic illustration of a triangulation sensing and analytic system for processing data from an energy consuming system. The triangulation sensing and analytic system 100 can include a data collection subsystem 102 in communication with one or more sensing nodes 105 and in communication with a Triangulation, Business Intelligence and Analytics engine 104. Sensing nodes 105 can include a plurality of sensors one through “n” that represent a primary sensor 106 and it triangulation sensors 108, 110 and 112. In one embodiment, at least three sensors 106, 108 and 110 are used.

In energy consuming systems, a sensor measures the physical parameter (e.g., temperature, water flow, humidity, pressure, power usage, etc.), and the measurement is transmitted to data collection subsystem 102. The data collection subsystem 102 accepts data from each node 105 and sends it to the Business Intelligence and Analytics engine 104. The Business Intelligence and Analytics engine 104 analyzes the data from each node 105 based on the multiple same physical parameter point measurements and determines if the physical parameter data of the primary sensor 106 is correct. If the physical parameter data of the primary sensor 106 is correct, then the Business Intelligence and Analytics engine 104 continues to permit the control system to use that data point for its control loop and at the same time uses that data point for its analytics. If the primary data point is determined to be inaccurate (through the use of triangulation algorithms) then, an alert is generated and the Business Intelligence and Analytics engine 104 discards the use of the inaccurate sensor data for its decisions and instead, instructs the control loop to use the corrected value.

In this process, the data is filtered and analyzed through automatic engineering analysis and triangulation algorithms of the Business Intelligence and Analytics engine 104 before the data is used by control systems, engineers and operators for accurate control decision, engineering decision, and plant energy optimization. The filtered and analyzed data can maximize and improve the accuracy of decision-making for the energy consuming system 100.

For example, in Heating Ventilating and Air Conditioning (HVAC) systems inaccurate and faulty sensors are commonly encountered in chiller plant control and optimization. The sensor accuracy is critical in making control decisions, evaluating plant performance, and developing and implementing plant energy optimization strategies. Without triangulation of sensor data, the control sequences have no way of knowing that the single data point that it is using in its control loop is accurate. As a rule of thumb, a 1-degree lower than actual reading in supply chilled water for a chiller can cause a 1% efficiency drop. The triangulated Business Intelligence and Analytics algorithms would determine this data inaccuracy and instruct the system to disregard the single data point and use the correct triangulated data point. Once the inaccurate sensor is detected, to calibrate and repair the inaccurate sensor involves the efforts of multiple parties and consumes significant time. The energy analytics are slowed down and implementations of energy saving measures are delayed. In addition, the detection of faulty sensor is sometimes not explicit, and it needs multidimensional data and engineering analysis. In the current invention, the guesswork and time-consuming analysis is no longer necessary as the triangulated data point is used by the Business Intelligence and Analytics engine.

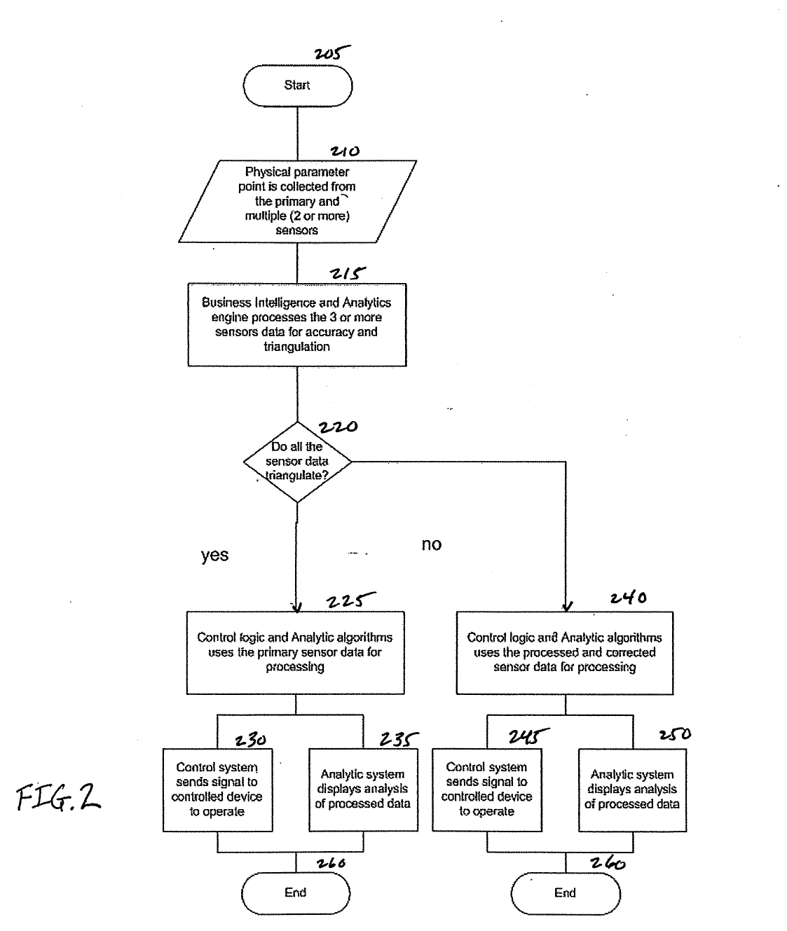

FIG. 2 is a flow chart illustrating a process for transforming real-time data of an energy consuming system into meaningful and useful data for optimizing the energy efficiency of the energy consuming system. Beginning in block 210, parameter point data from a primary sensor, a second sensor, and a third sensor is collected. In block 215, the Business Intelligence and Analytics engine processes the parameter point data from the primary sensor, the second sensor, and the third sensor for accuracy and triangulation. In block 220, a determination of whether the parameter point data from the primary sensor, the second sensor, and the third sensor successfully triangulated. If so, then in block 225, the Business Intelligence and Analytics engine will use the primary sensor data for processing. In block 230, a control signal is generated by the control system and sent to the controlled device of the energy consuming system and, in block 235, the Business Intelligence and Analytics engine will display the analysis of the processed data. Otherwise, in block 240, the Business Intelligence and Analytics engine will use the processed and corrected sensor data for processing. In this way, the triangulation algorithm automatically determines which of the three sensors is faulty and then uses the data points of the other two non-faulty sensors to obtain the triangulation value. In block 245, a control signal is generated by the control system and sent to the controlled device of the energy consuming system and, in block 250, the Business Intelligence and Analytics engine will display the analysis of the processed data.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, radiofrequency, and the like, or any suitable combination of the foregoing. Computer program code for carrying out operations for aspects of the present invention may be written in any combination of one or more programming languages, including an object oriented programming language and conventional procedural programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention have been described above with reference to flowchart illustrations and/or block diagrams of methods, apparatus (systems) and computer program products according to embodiments of the invention. In this regard, the flowchart and block diagrams in the Figures illustrate the architecture, functionality, and operation of possible implementations of systems, methods and computer program products according to various embodiments of the present invention. For instance, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

It also will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks. The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

Finally, the terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

Having thus described the invention of the present application in detail and by reference to embodiments thereof, it will be apparent that modifications and variations are possible without departing from the scope of the invention defined in the appended claims as follows:

We claim:

1. A method for transforming real-time data of an energy consuming system into meaningful and useful data for optimizing Bus Intelligence and Analytics decisions of the energy consuming system, the method comprising:
collecting parameter point data from a primary sensor;
collecting parameter point data from a second sensor;
collecting parameter point data from a third sensor;
processing the collected parameter point data from the primary sensor, the second sensor and the third sensor using a triangulation algorithm;
determining whether the sensor data triangulated;
selecting the parameter point data from the primary sensor when the sensor data triangulates;
selecting the parameter point data from the processed collected parameter point data from the primary sensor, the second sensor and the third sensor when the sensor data does not triangulate.

2. The method of claim 1, further comprising:
applying control logic to the parameter point data from the primary sensor when the sensor data triangulates; and
displaying an analysis of the parameter point data from the primary sensor.

3. The method of claim 1, further comprising:
applying control logic to the parameter point data from the processed collected parameter point data from the primary sensor, the second sensor and the third sensor when the sensor data does not triangulate; and
displaying the analysis of the processed collected parameter point data from the primary sensor, the second sensor and the third sensor.

4. The method of claim 3, further comprising:
generating a repair alert for the primary sensor.

5. The method of claim 3, further comprising:
generating a control signal to a device of the energy consuming system to operate.

6. A computer program product for transforming real-time data of an energy consuming system into meaningful and useful data for optimizing the energy efficiency of the energy consuming system, the computer program product comprising:
a computer readable storage medium having computer readable program code embodied therewith, the computer readable program code comprising:
computer readable program code for collecting parameter point data from a primary sensor;
computer readable program code for collecting parameter point data from a second sensor;
computer readable program code for collecting parameter point data from a third sensor;
computer readable program code for processing the collected parameter point data from the primary sensor, the second sensor and the third sensor using a triangulation algorithm;
computer readable program code for determining whether the sensor data triangulated;
computer readable program code for selecting the parameter point data from the primary sensor when the sensor data triangulates;
computer readable program code for selecting the parameter point data from the processed collected parameter point data from the primary sensor, the second sensor and the third sensor when the sensor data does not triangulate.

7. The computer program product of claim 6 further comprising:
computer readable program code for applying control logic to the parameter point data from the primary sensor when the sensor data triangulates; and
computer readable program code for displaying an analysis of the parameter point data from the primary sensor.

8. The computer program product of claim 6 further comprising:
computer readable program code for applying control logic to the parameter point data from the processed collected parameter point data from the primary sensor, the second sensor and the third sensor when the sensor data does not triangulate; and
computer readable program code for displaying the analysis of the processed collected parameter point data from the primary sensor, the second sensor and the third sensor.

9. The computer program product of claim 6 further comprising:
computer readable program code for generating a repair alert for the primary sensor.

10. The computer program product of claim 6 further comprising:
computer readable program code for generating a control signal to a device of the energy consuming system to operate.
